(19) United States
(12) Patent Application Publication
(10) Pub. No.: US 2006/0115101 A1
(43) Pub. Date: Jun. 1, 2006

(54) Multiple amplifier synchronization system

(76) Inventor: Michael A. Schoenberger, Cincinnati, OH (US)

Correspondence Address: DVA/PIONEER AUTOMOTIVE TECHNOLOGIES, INC.;INTELLECTUAL PROPERTY DEVELOPMENT, 2355 MAIN STREET, SUITE 200, IRVINE, CA, 94614, US

(21) Appl. No.: 11/164,313

(22) Filed: Nov. 17, 2005

Related U.S. Application Data
(60) Provisional application No. 60/522,893, filed on Nov. 18, 2004.

(51) Int. Cl. H03F 21/00; H03F 3/68

(52) U.S. Cl. 381/120; 330/295; 381/80

(57) ABSTRACT

The present invention allows multi-amplifier systems to be implemented, while avoiding the difficulties associated with current multi-amplifier systems. One amplifier is a “master”, which controls the settings a plurality of other amplifiers (the slaves). If an adjustment needs to be made, only the master needs to be adjusted. The amplifier of the present invention is configured to operate in a plurality of modes. In one configuration, the amplifier is set to be in a “master mode”. In another configuration, the amplifier is set to be in a “slave mode”. In yet another configuration, the amplifier is set to be in a “slave-inverse mode”.

### CROSS-REFERENCE TO RELATED APPLICATIONS

This application herein incorporates by reference and claims the benefit of U.S. Provisional Application Ser. No. 60/522,893, filed on Nov. 18, 2004, entitled Multiple Amplifier Synchronization System.

### NOTICE OF MATERIAL SUBJECT TO COPYRIGHT PROTECTION

All of the material in this patent document is subject to copyright protection under the copyright laws of the United States and of other countries. Portions of the material in this patent document are also subject to protection under the maskwork registration laws of the United States and of other countries. The owner of the copyright and maskwork rights has no objection to the facsimile reproduction by anyone of the patent document or the patent disclosure, as it appears in the United States Patent and Trademark Office file or records, but otherwise reserves all copyright and maskwork rights whatsoever.

### BACKGROUND OF THE INVENTION

1. Field of the Invention

The present invention relates generally to audio amplifiers, and more specifically to controlling a multiple amplifier system.

2. Background of the Invention

It is common to connect multiple amplifiers together in a cascade or daisy-chain. Current multiple amplifier cascades may be performed in one of two manners. In a four amplifier system, for instance, an unprocessed audio input signal is divided into four signals and each signal is handled by all of the four amplifiers independently. Alternatively, if the amplifier has a pass through, then the four amplifier system would be daisy-chained together and the unprocessed signal would enter an amplifier in the chain and be passed directly out of the amplifier to the next amplifier.

One problem associated with such an arrangement is that each amplifier is equivalent in the chain and acts independently. This means that if an adjustment to the audio signal needs to be made, each amplifier in the chain needs to be adjusted the same. In such an arrangement, adjusting and fine-tuning the system becomes burdensome, especially when there are many amplifiers in the daisy-chain.

Typically the user would first fine-tune a first amplifier, for instance by adjusting bass boost, frequency, volume, gain, crossover (filter frequency) etc. Then these exact same adjustments would need to be performed on every other amplifier. If many amplifiers are cascaded in this manner, making any adjustment, no matter how minor, can become overly burdensome.

It undesirable to have to manually adjust and fine-tune each and every amplifier in a daisy chain because of the time involved in the process.

### BRIEF DESCRIPTION OF THE DRAWINGS

The invention will be more fully understood by reference to the following drawings, which are for illustrative purposes only:

FIG. 1 is a system diagram showing one embodiment of the present invention.

FIG. 2 is a system diagram showing another embodiment of the present invention.

FIG. 3 is a diagram of a multiple amplifier system in slave-inverse mode according to an embodiment of the present invention.

FIG. 4 is a diagram of a multiple amplifier system in slave mode according to an embodiment of the present invention.

FIG. 5 is a diagram showing an ordering for an initial gain adjustment in a multiple amplifier system according to an embodiment of the present invention.

### SUMMARY OF THE INVENTION

The present invention allows multi-amplifier systems to be implemented, while avoiding the difficulties associated with current multi-amplifier systems. One amplifier is a “master”, which controls the settings a plurality of other amplifiers (the slaves). If an adjustment needs to be made, only the master needs to be adjusted. The amplifier of the present invention is configured to operate in a plurality of modes. In one configuration, the amplifier is set to be in a “master mode”. In another configuration, the amplifier is set to be in a “slave mode”. In yet another configuration, the amplifier is set to be in a “slave-inverse mode”.

According to an embodiment of the present invention, each amplifier in a cascade has a signal processing block and an amplifier synchronization block. Depending on whether the signal processing block or the amplifier synchronization block is used, any give amplifier can be configured and/or reconfigured as a master or a slave.

The audio signal is carried through the signal processing block of an amplifier configured as a master, and then output to one or more amplifiers configured as slaves. The slaves receive the master's output as input in the form of a completely processed audio signal. The audio signal bypasses the signal processing block of the slave and passes through its synchronization block. The synchronization block handles the audio signal in one of a plurality of modes, depending on a position of an internal switch, and carries the signal to the next slave in the cascade, and the process repeats.

In this manner, only the amplifier set to be the master carries the audio signal through its signal processing block. If an adjustment is made to the signal being carried through the master, the modified audio signal is propagated to all of the amplifiers set to be slaves, thereby eliminating the need to make any adjustment to the slaves.

### DETAILED DESCRIPTION OF THE INVENTION

The present invention allows multi-amplifier systems to be implemented, while avoiding the difficulties associated with current multi-amplifier systems. One amplifier is a “master”, which controls the settings a plurality of other amplifiers (the slaves). If an adjustment needs to be made, only the master needs to be adjusted. The amplifier of the present invention is configured to operate in a plurality of modes. In one configuration, the amplifier is set to be in a “master mode”. In another configuration, the amplifier is set to be in a “slave mode”. In yet another configuration, the amplifier is set to be in a “slave-inverse mode”.

According to an embodiment of the present invention, each amplifier in a cascade has a signal processing block and an amplifier synchronization block. Depending on whether the signal processing block or the amplifier synchronization block is used, any give amplifier can be configured and/or reconfigured as a master or a slave.

The audio signal is carried through the signal processing block of an amplifier configured as a master, and then output to one or more amplifiers configured as slaves. The slaves receive the master's output as input in the form of a completely processed audio signal. The audio signal bypasses the signal processing block of the slave and passes through its synchronization block. The synchronization block handles the audio signal in one of a plurality of modes, depending on a position of an internal switch, and carries the signal to the next slave in the cascade, and the process repeats.

In this manner, only the amplifier set to be the master carries the audio signal through its signal processing block. If an adjustment is made to the signal being carried through the master, the modified audio signal is propagated to all of the amplifiers set to be slaves, thereby eliminating the need to make any adjustment to the slaves.

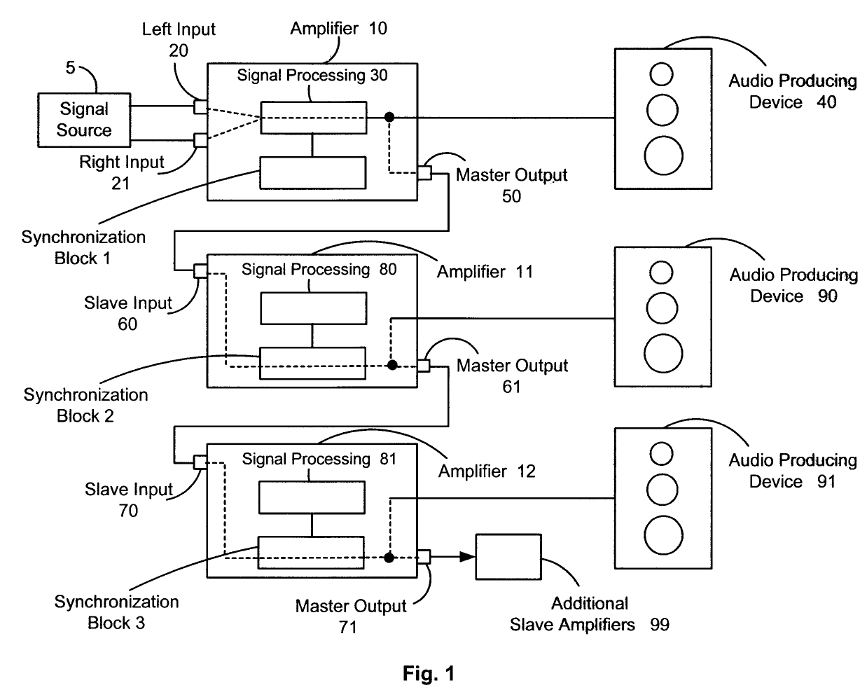

FIG. 1 is a system diagram showing one embodiment of the present invention. Amplifiers 10, 11, and 12 have signal processing blocks 30, 80, and 81, as well as synchronization blocks 1, 2, and 3. Amplifiers 10, 11, and 12 are connected in a daisy-chain type cascade, but it is understood that more than three amplifiers may be configured in such an arrangement as well. The diagram of FIG. 1 is limited to three amplifiers for simplicity.

In FIG. 1 a signal source 5 feeds left and right inputs of amplifier 10. The signal is carried through signal processing block 30 and then to audio producing device 40, such as a speaker, bypassing synchronization block 1, since amplifier 10 is set to be the master. Signal source 5 is also routed through master out 50 of amplifier 10 and to slave input 60 of amplifier 11. The signal 5 is carried through synchronization block 2, where it is handled in one of a plurality of modes, and then to master out 61 of amplifier 11, wherein signal processing block 80 is bypassed, since amplifier 10 is set to be a slave.

Signal 5 is also routed to audio producing device 90. Once exiting master out 61, the signal is carried to slave input 70 of amplifier 12. The signal 5 bypasses signal processing block 81 and is carried through synchronization block 3, where it is handled in one of a plurality of modes, and then to and is sent to audio producing device 91. Signal 5 is also routed through master out 71 to additional slave amplifiers 99, if necessary.

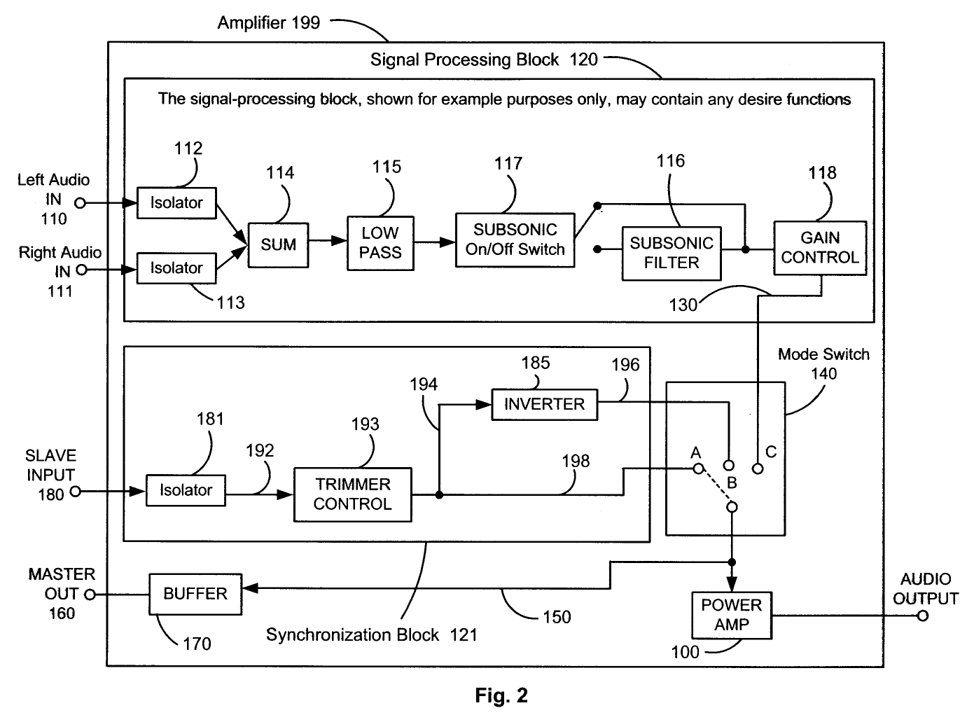

FIG. 2 is a system diagram showing another embodiment of the present invention. The power amplifier of FIG. 2 is any single ended class of audio amplifier where the positive output terminal is an active terminal and the negative terminal is connected to ground. Left and right audio signal 110 and 111 originate from a source, for instance a head-unit. There are three modes of operation that the amplifier, shown in FIG. 2, can be configured: master mode; slave-inverse mode; and slave mode.

Master Mode

In “master mode” the amplifier 199 is the first or master amplifier in a daisy-chain. When it is determined that the present amplifier 199 will be a master, it is configured as such. In general, the master amplifier will be configured where it will receive audio signals as input and carry them through a signal processing block, skipping the synchronization block, and after the audio signals are completely processed, they are outputted to the next amplifier in the daisy-chain, which is typically designated as a slave.

More specifically, the source will send audio signals to the left and right audio inputs 110 and 111 of the master amplifier only. Then the signal will proceed through a signal processing block 120 to signal path 130 where processed audio is ready to be fed to the power amplifier 100 inside amplifier 199.

The signal processing block 120 in the present example receives the audio input 110 and 111 and passes it through isolators 112 and 113 to summing block 114, through low pass block 115, through subsonic block 116 if subsonic switch 117 is in a first position and if the switch 117 is in a second position, then the signal bypasses subsonic block 116 to gain control 118 and out of the signal processing block 120.

The present example of signal processing block 120 is shown for illustration purposes only. Signal processing block 120 may contain other elements or functions known by those skilled in the art to make an amplifier, for instance low pass filter (LPF), gain, bass boost, etc., may also be used.

After leaving signal processing block 120 along signal path 130, the signal is routed through a mode switch 140. Mode switch 140 is a three-position switch in this example, enabling operation in the 3 modes described herein. In master mode, the signal is routed through switch 140 to signal path 150, which feeds the power amplifier block 100 and the buffer block 170. The buffer block 170 feeds a signal to the master out connection 160. The master out connection 160 will send a signal to a slave amplifier, which is the next amplifier in the daisy-chain. It should be noted that in the present configuration of switch 140, synchronization block 121 is bypassed.

Slave-Inverse Mode

In “slave-inverse mode”, amplifier 199 will be configured as a slave to a master. The same amplifier 199 shown in FIG. 2 is discussed, since all amplifiers, whether slaves or masters can have the same components (although it is not required), but it should be understood that the current discussion of FIG. 2 in slave-inverse mode, may be describing a different physical amplifier than the amplifier discussed with respect to master mode. If it is determined that the present amplifier in the daisy-chain needs to be in slave-inverse mode, then it is configured as such. In this case the amplifier will become a slave to a master. In general, in a bridging configuration of multiple amplifiers, also called a bridge-to-load configuration (BTL), the slaves should be in slave-inverse mode.

The speaker system in a BTL configuration looks for a potential between two points. When multiple amplifiers are bridged to a speaker, for instance the positive terminal of the speaker to a first amplifier and the negative terminal of the speaker to a second amplifier the signals will cancel out to zero and the speaker will find no potential with which to operate and convey sound. In such a scenario, one of the signals must be inverted and out of phase in order for the speaker to operate. In such a bridging configuration, the slave amplifier should be set to slave-inverse mode.

More specifically, the signal of the slave audio output is inverted at block 185 compared to the master audio output connection 160. This inverted relationship allows the amplifiers to drive a speaker in the BTL configuration. The signal-processing block 120 is bypassed during slave-inverse mode operation to allow the master amplifier to perform the signal processing and only synchronization block 121 is used.

The audio source is fed to the “slave input” connection 180 which is ground isolated at block 181 and then transferred to signal path 192. Signal path 192 feeds the trimmer control 193, which allows a small amount of adjustment if needed. The trimmer control 193 feeds the trimmed signal to signal path 194, which is then inverted at block 185 and transferred to signal path 196. Signal path 196 is routed through the mode switch 140 to signal path 150 that feeds the power amplifier block 100 and the buffer block 170. The buffer block 170 feeds a signal to the master out connection 160. The master out connection 160 will send a signal to the next slave amplifier, which is the next amplifier in the daisy-chain.

Slave Mode

In “slave mode” the amplifier 199 is a slave to the master. Again, it should be noted that the discussion of slave mode refers to FIG. 2, but conceptually, the amplifier 199 discussed here with respect to FIG. 2 may be a different amplifier than that discussed with respect to master mode or slave-inverse mode. Since all amplifiers, whether master or slave can have identical functionality, the master and slave amplifiers can be the same devices, set to operate in different ways, one as a master, others as slaves, or alternatively an amplifier configured as a master can be re-configured to operate in one of the slave modes.

An amplifier should be set to slave mode if the amplifier is a slave in a daisy-chain and the signal does not need to be inverted. One such scenario is when multiple amplifiers are set up in a non-bridging configuration. In a non-bridging configuration, each amplifier controls its own audio output device (speaker). In such a scenario, if the sounds are inverted, then the sound from one speaker would cancel out the sound from another speaker, which is undesirable.

Therefore, in the non-bridging configuration, it is desirable to have each speaker output sound that is in phase. In general, that means that a slave in the present mode will receive completely processed audio signals from a master or prior slave, bypass any signal processing blocks within the unit, and use the synchronization block within the unit, but in such a manner that the signal is not inverted before being buffered and amplified.

Specifically, the signal of the slave audio output is non-inverted compared to the master audio output connection 160. This non-inverted relationship allows the amplifiers to drive multi-speaker system in phase. The signal-processing block 120 is bypassed during slave operation to allow the master amplifier to perform the signal processing, and only synchronization block 121 is used. The audio source is fed to the slave input connection 180 that is ground isolated at block 181 then transferred to signal path 192. Signal path 192 feeds the trimmer control 193, which allows a small amount of adjustment if needed.

The trimmer control 193 feeds the trimmed signal to signal path 198. Signal path 198 is routed through the mode switch 140 to signal path 150 that feeds the power amplifier block 100 and the buffer block 170. The buffer block 170 feeds a signal to the master out connection 160. The master out connection 160 sends a signal to the next slave amplifier, which is the next amplifier in the daisy-chain.

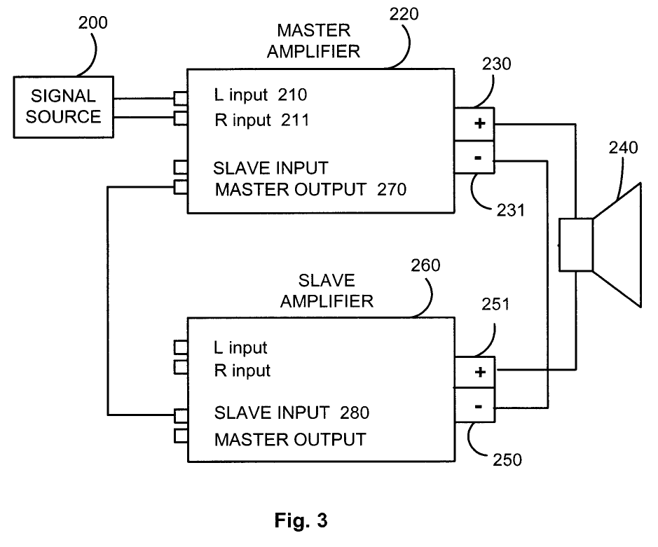

FIG. 3 is an example of a multiple amplifier system in slave-inverse mode according to an embodiment of the present invention. Signal source 200 provides left and right inputs 210 and 211 to master amplifier 220. Positive terminal 230 is routed to an audio producing device 240 while negative terminal 231 is routed to negative terminal 250 of slave amplifier 260. Positive terminal 251 of slave amplifier 260 is routed to audio device 240 as well. Master output 270 of master amplifier 220 is connected to slave input 280 of slave amplifier 260. It is understood to one having ordinary skill in the art that note that more amplifiers may be added to the daisy-chain in FIG. 3 in addition to master amplifier 220 and slave amplifier 260.

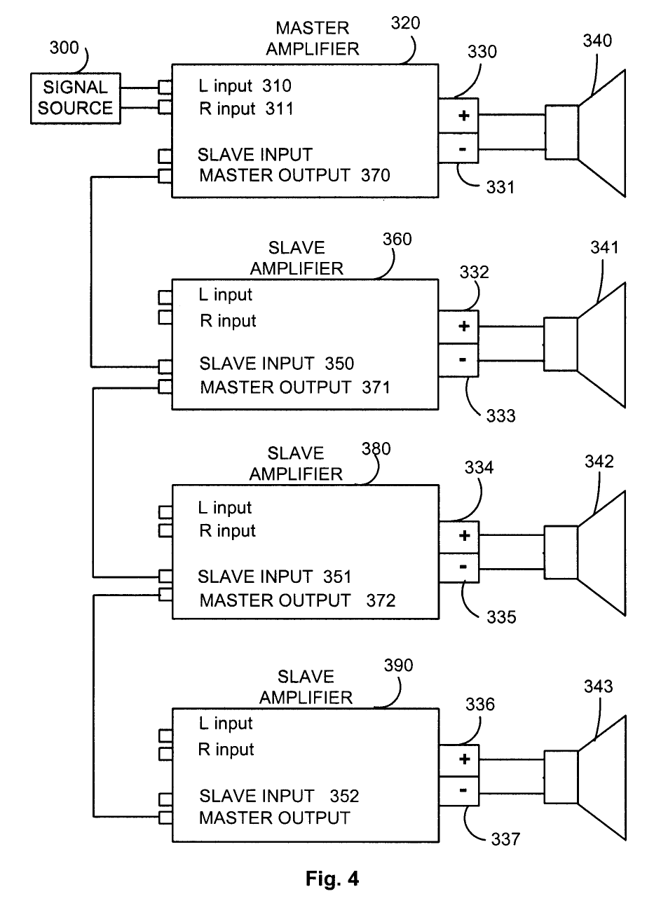

FIG. 4 is an example of a multiple amplifier system in slave mode according to an embodiment of the present invention. Signal source 300 provides left and right inputs 310 and 311 to master amplifier 320. Positive terminal 330 and negative terminal 331 are routed to an audio producing device 340. Master output 370 of master amplifier 320 is connected to slave input 350 of slave amplifier 360, while positive and negative terminals 332 and 333 of slave amplifier 360 are connected to audio producing device 341.

Master output 371 of slave amplifier 360 is connected to slave input 351 of slave amplifier 380, while positive and negative terminals 334 and 335 of slave amplifier 380 are connected to audio producing device 342. Master output 372 of slave amplifier 380 is connected to slave input 352 of slave amplifier 390, while positive and negative terminals 336 and 337 of slave amplifier 360 are connected to audio producing device 343. It is understood to one having ordinary skill in the art that note that more amplifiers may be added to the daisy-chain in FIG. 4 in addition to master amplifier 320 and slave amplifiers 360, 380, and 390.

Table 1 shows the amplifier of the present invention in various possible states depending on the configuration desired:

TABLE 1

| | | Signal | Amplifier | |
|---|---|---|---|---|
| | | Processing | Synchronization | |
| Mode | Switch | Block | Block | Inverter |
| Master | Position 1 | Active | Inactive | Inactive |
| Slave | Position 2 | Inactive | Active | Inactive |
| Slave- | Position 3 | Inactive | Active | Active |
| Inverse | | | | |

Amplifier Adjustment

The following procedure shows how to adjust amplifier gain for master-slave operation. During master-slave operation amplifiers are connected in a daisy-chain configuration as shown in FIGS. 1-4. This configuration allows the slave amplifiers to copy the master's settings. This makes adjustment simple because only the master amplifier needs adjustment to change all amplifiers in the cascade. For example, if a sub-sonic filter needs to be turned on, only the master amplifier's sub-sonic switch needs to be changed. All slave amplifiers follow the master amplifier's settings and ignore their own settings. Only one initial adjustment needs to be made to each slave amplifier after installation to balance the output signal level.

Because each amplifier's gain can vary a small amount a gain trimmer adjustment is incorporated for each sync amplifier in one embodiment of the invention. This trimmer can vary the synced amplifier's gain plus or minus 3 dB independent of the master amplifier's gain adjustment. This allows all amplifiers to be balanced to each other. Once balanced no more adjustments should be needed to slaved amplifiers. All other adjustments will be preformed on the master.

There are two ways to perform the initial gain adjustment of slaved amplifiers. In a first method, each synced amplifier's gain control is set to the normal position. This will balance the output volumes sufficiently for most applications. With gains set to normal each amplifier's output should be approximately within a volt of each other.

In a second method for performing the initial gain adjustment, each slaved amplifier's gain setting can be deviated from the normal position to set its output voltage to the master's voltage level. Once this is done for each slaved amplifier, all amplifiers will have the same voltage output.

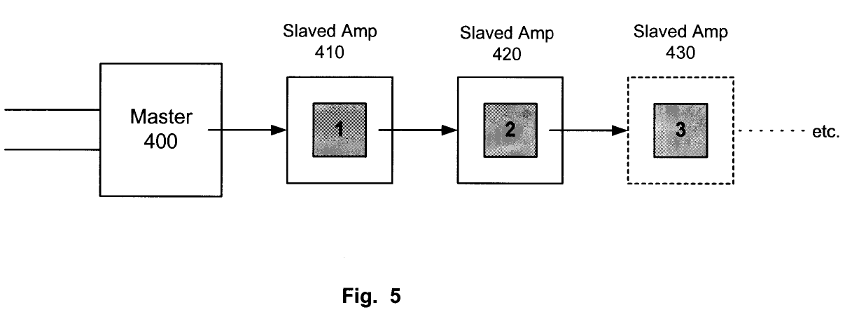

To properly perform this adjustment, the order shown in FIG. 5 should be followed. The daisy-chain in the example of FIG. 5 includes the master amp 400 and three slaved amps 410, 420, and 430. The gain should be adjusted first on slaved amp 410, then on slaved amp 420, then on slaved amp 430, in that order.

A sin wave source should be used at low output level for setup. It is important to use low output level during this setup because sin waves can over stress a system quickly. A sin wave allows a voltmeter to be used for measuring output levels. Below are the steps to adjust slaved gain.

1. Connect sin wave to system adjust for low output level.

2. Use voltmeter to measure master's output voltage level.

3. Use volt meter to measure slaved amplifier output voltage level.

4. Match slaved amplifier output to master's output using gain adjustment on synced amp.

5. Repeat for each slaved amplifier in proper order shown above.

Although the description above contains many specificities, these should not be construed as limiting the scope of the invention but as merely providing illustrations of some of the presently preferred embodiments of this invention. Thus the scope of this invention should be determined by the appended claims and their legal equivalents.

What is claimed is:

1. An apparatus comprising:
a first amplifier with a first signal processing block and a first synchronization block;
a second amplifier with a second signal processing block and a second synchronization block;
a connection between the first and second amplifiers, wherein an audio signal is provided as input to said first amplifier, carried through said first signal processing block, through said connection, and through said second synchronization block of said second amplifier, and to an output.

2. The apparatus of claim 1 wherein said second synchronization block includes a switch and an inverter, and wherein said audio signal is inverted within said second signal processing block when said switch is in a first position.

3. The apparatus of claim 1 wherein said second synchronization block includes a switch and an inverter, and wherein said audio signal bypasses said inverter within said second signal processing block when said switch is in a second position.

4. The apparatus of claim 1 wherein said second synchronization block includes a trimmer for further adjusting said audio signal at said second amplifier.

5. The apparatus of claim 1 further comprising first and second audio producing devices, wherein said first and second amplifiers include first and second outputs which carry said audio signal to said first and second audio producing devices.

6. An amplifier synchronization apparatus comprising:
a slave input means;
a master out means;
a synchronization means between said slave input means and said master out means for receiving a processed audio signal and for outputting said processed audio signal in one or more modes.

7. The amplifier synchronization apparatus of claim 6, further comprising a switch, wherein when said switch is in a first position, said processed audio signal is handled in a first mode.

8. The amplifier synchronization apparatus of claim 6, further comprising a switch, wherein when said switch is in a second position, said processed audio signal is handled in a second mode.

9. The amplifier synchronization apparatus of claim 8 further comprising an inverter between said slave input means and said master out means, wherein said processed audio signal in said second mode is inverted by said inverter before being outputted to said master out means.

10. The amplifier synchronization apparatus of claim 7 further comprising an inverter between said slave input means and said master out means, wherein said processed audio signal in said first mode bypasses said inverter and is output to said master out means.

11. A method for connecting multiple amplifiers comprising:
providing a first amplifier with a first signal processing block and a first synchronization block in a first mode;
providing a second amplifier with a second signal processing block and a second synchronization block in a second mode;
connecting the first and second amplifiers, wherein an audio signal is provided as input to said first amplifier, carried through said first signal processing block, through said connection, and through said second synchronization block of said second amplifier, and to an output.

12. The method of claim 11 wherein said second synchronization block includes a switch and an inverter, further comprising:
inverting said audio signal in said second signal processing block, when said switch is in a first position.

13. The method of claim 11 wherein said second synchronization block includes a switch and an inverter, further comprising:
bypassing said inverter within said second signal processing block with said audio signal, when said switch is in a second position.

14. The method of claim 11, further comprising:
providing a trimmer in said second synchronization block for further adjusting said audio signal at said second amplifier.

15. The method of claim 11 including first and second audio producing devices, further comprising:
carrying said audio signal to said first and second audio producing devices from first and second outputs in said first and second amplifiers.
